(19) United States
(12) Patent Application Publication
(10) Pub. No.: US 2011/0008949 A1
(43) Pub. Date: Jan. 13, 2011

(54) ADHESIVE SHEET FOR DICING SEMICONDUCTOR WAFER AND METHOD FOR DICING SEMICONDUCTOR WAFER USING THE SAME

(75) Inventors: Toshimasa SUGIMURA, Ibaraki-shi (JP); Tomokazu Takahashi, Ibaraki-shi (JP); Noriyoshi Kawashima, Ibaraki-shi (JP); Fumiteru Asai, Ibaraki-shi (JP)

Correspondence Address: SUGHRUE MION, PLLC, 2100 PENNSYLVANIA AVENUE, N.W., SUITE 800, WASHINGTON, DC, 20037, US

(73) Assignee: NITTO DENKO CORPORATION, Osaka (JP)

(21) Appl. No.: 12/830,543

(22) Filed: Jul. 6, 2010

(30) Foreign Application Priority Data
Jul. 7, 2009 (JP) 2009-160380

(51) Int. Cl. H01L 21/78; C09J 7/02

(52) U.S. Cl. 438/464; 428/354; 428/339; 428/335; 257/E21.599

(57) ABSTRACT

An adhesive sheet for dicing a semiconductor wafer having a laminate comprises; a base film, an intermediate layer and an adhesive layer, the intermediate layer is formed by a thermoplastic resin having a melting point of 50 to 100° C.; and the base film has a higher melting point than the intermediate layer as well as a method for dicing a semiconductor wafer comprises the steps of: adhering the adhesive sheet according to the above to a corrugated surface of a semiconductor wafer, and dicing the semiconductor wafer.

### CROSS-REFERENCE TO RELATED APPLICATIONS

This application claims priority to Japanese Patent Application No. JP2009-160380 filed on 7 Jul. 2009. The entire disclosure of Japanese Patent Application No. JP2009-160380 is hereby incorporated herein by reference.

### BACKGROUND

1. Technical Field

The present invention relates to an adhesive sheet for dicing a semiconductor wafer and method for dicing a semiconductor wafer using the same.

2. Related Art

In recent years, system in package (SiP) in which a plurality of semiconductor chips is mounted in a single semiconductor package represents an extremely important technology to realize high performance and downsizing of electronic devices. Current SiP products mainly employ a method in which LSI chips are laminated, and then a bump electrode on each laminated chip and a circuit board are wired using a wire bonding technique.

On the other hand, a method of laminating a chip having a through electrode is also employed as a technique for realizing high reliability packaging at a higher density. A bump electrode having a height of 1 to 50·m is formed on both surfaces of a semiconductor wafer including a through electrode to thereby form a semiconductor wafer with corrugation (i.e., irregularity, or concavity and convexity) on both surfaces.

When dicing this type of semiconductor wafer, an adhesive sheet for dicing is attached to one surface of the semiconductor wafer, in which the adhesive surface includes a corrugation caused by the bump electrode. As a result, a conventional dicing tape cannot be adapted to follow the contour of the corrugation on the wafer surface and therefore does not enable complete attachment. Consequently, during dicing, there is a tendency for chip fly-off, contamination resulting from cutting water and cutting residue, damage to chips or the like, and thereby there have been problems including a conspicuous reduction in chip reliability and a conspicuous deterioration in productivity.

In this regard, a dicing tape has been proposed which protects a semiconductor wafer having surface corrugations from cutting residue and cutting water during dicing (for example, JP-2001-203255-A).

This dicing tape prevents damage to the wafer or contamination by cutting water by embedding the corrugations of the semiconductor wafer having a bump electrode in an intermediate layer having an elastic coefficient of 30 to 1000 kPa.

Furthermore, a process of dicing has been proposed in which air bubbles are introduced into an adhesive layer and the bump electrodes of the semiconductor wafer is embedded into the adhesive layer (for example, JP-2006-13452-A).

However when the intermediate layer or the adhesive layer is too soft, the problem arises that there is a conspicuous deterioration in productivity and reliability resulting from chip breakage (chipping).

### SUMMARY

The present invention is proposed in light of the above problems, and has the object of providing an adhesive sheet adapted for dicing a semiconductor wafer and a method for dicing a semiconductor wafer using the sheet that enables superior contour tracking (i.e., conforming or following) properties for corrugations and which enables prevention of water penetration to the adhesive surface of the adhesive sheet, contamination, chip fly-off, chipping and the like even when corrugations or the like are present on a surface of a semiconductor wafer.

The present invention provides an adhesive sheet for dicing a semiconductor wafer having a laminate comprising; a base film, an intermediate layer and an adhesive layer, the intermediate layer is formed by a thermoplastic resin having a melting point of 50 to 100° C.; and the base film has a higher melting point than the intermediate layer.

Further, the present invention provides a method for dicing a semiconductor wafer comprising the steps of: adhering an adhesive sheet according to the above to a corrugated surface of a semiconductor wafer, and dicing the semiconductor wafer.

The present invention is possible to provide an adhesive sheet for dicing a semiconductor wafer that enables superior contour tracking properties for corrugations, and enables prevention of water penetration to the adhesive surface of the adhesive sheet, contamination, chip fly-off, chipping and the like even when corrugations or the like are present on the surface of the semiconductor wafer can be provided.

Further, a method for dicing a semiconductor wafer can be provided that enables improvement of the fabrication yield.

### DETAILED DESCRIPTION OF EXEMPLARY EMBODIMENTS

An adhesive sheet for dicing a semiconductor wafer according to the present invention is mainly formed by a laminate having a base film, an intermediate layer and an adhesive layer.

Generally, the intermediate layer is preferably disposed between the base film and the adhesive layer. The intermediate layer may be adapted to be formed by a thermoplastic resin.

Examples of the thermoplastic resin include, for example, polyethylene (PE); polybutene; ethylene-based copolymer or polyolefin-based copolymer such as ethylene-propylene copolymer (EPM), ethylene-propylene-diene copolymer (EPDM), ethylene-ethyl acrylate copolymer (EEA), ethylene-acrylic ester-maleic anhydride copolymer (EEAMAH), ethylene-glycidyl methacrylate copolymer (EGMA), ethylene-methacrylate copolymer (EMAA), ethylene-vinyl acetate copolymer (EVA); thermoplastic elastomer such as butadiene-based elastomer, ethylene-isoprene-based elastomer, ester-based elastomer; thermoplastic polyester; polyamide-based resin such as polyamide 12 copolymer; polyurethane; polysthylene-based resin; cellophane; polyacryl ester; acrylic-based resin such as methyl methacrylate; polyvinylchloride such as vinylchloride-vinyl acetate copolymer and the like. Of these, at least one selected from the group consisting of ethylene-vinyl acetate copolymer, ethylene-alkyl acrylate copolymer, low-density polyethylene, ionomer is prefereble. These can be used alone or as mixture of two or more.

When the adhesive layer as described hereafter includes a radiation curing type adhesive, the intermediate layer may be adapted to be formed by a material (for example, a resin or the like having transparent properties) that enables transmission of at least a predetermined amount of radiation rays to thereby enable irradiation of radiation rays through the intermediate layer or the like.

The thermoplastic resin configuring the intermediate layer may be adapted to have a melting point of about 50 to 100° C., preferably about 50 to 95° C., preferably about 50 to 90° C., and still more preferably about 60 to 90° C. When the melting point is too low, the intermediate layer is softened due to the fact that the temperature approaches the ambient temperature during dicing, and therefore vibration or deformation of the intermediate layer tends to result from the dicing. That deformation or the like induces a positional deviation of the wafer which is the object undergoing cutting. In this manner, there is a risk of chip breakage, typically chipping, deterioration in cutting quality and the like. Furthermore there is a risk of problems including deformation of the intermediate layer in the same manner as the ambient temperature during product shipping or the like. When the melting point is too high, although the temperature increase enables adhesion to the semiconductor wafer by heating, problems are encountered in relation to mounting, safety and handling of adhesion and the like.

On the other hand, since the melting point of the intermediate layer is within this range, when the adhesive sheet adheres to a semiconductor wafer that includes a corrugation, the protrusion of the wafer surface which is the adhesive surface of the adhesive sheet is fixed by the intermediate layer, and strongly fixes the wafer during dicing to thereby enable suppression of wafer damage. In particular, since the adhesive sheet is adhered by heating to the wafer surface which includes a corrugation, accurate contour following onto a corrugation is enabled due to the suitable softening of the intermediate layer, and thus ensures prevention of chip fly-off, prevention of penetration of cutting water and cutting residue onto the wafer surface and protects the corrugations of the wafer. Furthermore since the temperature is returned to room temperature during dicing, the intermediate layer becomes hard, and thereby retains the position of the wafer chip. Consequently the wafer chip is not displaced even by vibration during dicing and thereby prevents chip damage such as chipping or the like and ensures superior accuracy in productivity and reliability.

As used herein, “melting point” means a value measured using JIS K 7121 at DSC.

The thickness of the intermediate layer may be suitably adjusted within a range in which wafer retention and protective properties are not adversely affected. For example, 3 to 200·m is suitable, 3 to 150·m is preferred, 3 to 120·m is more preferred, and 5 to 120·m is still more preferred. When the thickness of the intermediate layer is too small, contour tracking to the corrugations on the semiconductor wafer surface becomes difficult, and chip fly-off or contamination during dicing caused by cutting residue or cutting water occurs. Conversely, when the thickness of the intermediate layer is too large, operational efficiency is adversely affected by the time required for adhering the adhesive sheet and the reduction in dicing accuracy causes problems such as chip breakage or maintaining product shape during thermal lamination. On the other hand, when the thickness of the intermediate layer is in this range, if lamination is executed at the melting point of the intermediate layer, contour tracking properties onto the protrusions on the semiconductor wafer surface are improved.

The base film may be adapted to be formed by a material having a higher melting point than the intermediate layer. For example, a melting point at least 20° C. higher than the intermediate layer is preferred, at least 25° C., furthermore at least 30° C., and at least 40° C. higher than the intermediate layer are preferred. Although a softening point and the like depends on the type of the base film, when the temperature difference between the melting point of the intermediate layer and the softening point of the base film is small, adhesion between the semiconductor wafer and the adhesive sheet cannot be stably executed. On the other hand, when the temperature difference between the melting point of the intermediate layer and the softening point of the base film is large, stable adhesion is enabled even under heated conditions.

The base film may use a polyester-based film such as polyester (PET), polyethylene naphthalate (PEN), polybutylene terephthalate (PBT) or the like; an aromatic polyimide-based film such as polyimide (PI) or the like; and a polyolefin-based film such as polypropylene (PP) or the like. These materials can be used alone or as mixture of two or more materials. The base film may be a single layer or may be a laminated structure of two or more layers.

The thickness of the base film may be adapted to be generally of about 5 to 400·m, preferably of about 10 to 300·m, and still more preferably of about 30 to 200·m.

When the adhesive layer as described hereafter includes a radiation curing type adhesive, the base film is configured by a material (for example, a resin or the like having transparent properties) that enables transmission of at least a predetermined amount of radiation rays to thereby enable irradiation of radiation rays through the base film or the like.

The base film may be formed by a known method for film formation, for example, a wet-casting method, an inflation method, a T-die extrusion method or the like. The base film may be either non-stretched, or subjected to a uniaxial or biaxial stretching process.

The intermediate layer may be formed separately from the base film using a method described above, or may be laminated onto the base film, or may be formed at the same time as the base film using a method described above.

One surface or both surfaces of the base film and the intermediate layer may be subjected to a physical or chemical process using a mat process, a corona process, a plasma process, a primer process, a cross-linking process (chemical cross-linking (silane)) or the like. In particular, it is preferred that any one of these processes is performed on the laminated side of the adhesive layer with the intermediate layer.

The adhesive layer may use a known adhesive used in this field, for example, a pressure-sensitive adhesive.

More specifically, various types may be used including an acrylic-based adhesive, a silicone-based adhesive, a rubber-based adhesive or the like. Of these, an acrylic-based adhesive using an acrylic-based polymer as a base polymer is preferred in view of adhesive properties in relation to the semiconductor wafer, and cleaning and washing properties of the semiconductor wafer after separation using an organic solvent such as alcohol and ultrapure water, and the like.

Examples of the acrylic polymer include an acrylic polymer derived from one monomer or at least 2 monomers, for example, an alkyl ester of a (meth)acrylic acid, i.e., a C₁ to C₃₀ (especially it is preferable linear or branched C₄ to C₁₈) alkyl (meth)acrylate, such as methyl (meth)acrylate, ethyl (meth)acrylate, propyl (meth)acrylate, isopropyl (meth)acrylate, butyl (meth)acrylate, isobutyl (meth)acrylate, sec-butyl (meth)acrylate, tert-butyl (meth)acrylate, pentyl (meth)acrylate, isopentyl (meth)acrylate, 2-ethylhexyl (meth)acrylate and octyl (meth)acrylate, as well as cycloalkyl (meth)acrylate, such as cyclopentyl (meth)acrylate and cyclohexyl (meth)acrylate. These monomers can be used alone or as mixture of two or more monomers.

The amount of the acrylic monomers is preferable about 60 to 99 wt % with respect to the total monomer constituting the polymer contained in the adhesive.

In this specification, the (meth)acrylate means at least one of acrylate or methacrylate.

The acrylic polymer may be a copolymer that is copolymerized with the above monomer and another copolymerizable monomer, as needed, for the purpose of modifying the cohesive force, heat resistance and the like.

Examples of such another monomer include;

a carboxyl- or acid anhydride-containing monomer such as (meth)acrylic acid, crotonic acid, carboxyethyl (meth)acrylate, carboxypentyl (meth)acrylate, itaconic acid, fumaric acid, maleic acid, maleic anhydride and itaconic anhydride;

a hydroxyl group-containing monomer such as 2-hydroxyethyl (meth)acrylate, 4-hydroxybutyl (meth)acrylate, 6-hydroxyhexyl (meth)acrylate, 8-hydroxyoctyl (meth)acrylate, 10-hydroxydodecyl (meth)acrylate, 12-hydroxyrauryl (meth)acrylate, (4-hydroxymethyl cyclohexyl) methyl(meth)acrylate;

a sulfonate-containing monomer such as styrenesulfonate, allylsulfonate, 2-(meth)acrylamide-2-methyl propanesulfonate, (meth)acrylamide propanesulfonate, sulfopropyl (meth)acrylate, (meth)acryloyl oxynaphthalenesulfonate;

a phosphate-containing monomer such as 2-hydroxyethyl acryloylphosphate;

an amino-containing monomer such as morpholino (meth)acrylate, t-butylaminoethyl (meth)acrylate.

Examples of such another monomer may further include;

a vinyl ester such as vinyl acetate;

a styrene monomer such as styrene;

a cyano-containing monomer such as acrylonitrile;

a cyclic or non-cyclic (meth)acrylic amide; and a variety of other such monomers known as a monomer for the modification of the acrylic pressure sensitive adhesives.

Of these, it is preferable (meth)acrylic acid, and more preferably acrylic acid. These monomers are useful because of generating cross-linkage bond in the polymer.

These monomers can be used alone or as mixture of two or more monomers.

The amount of the other copolymerizable monomers is preferable about 50 wt % or less, and more preferably about 1 to 40 wt % with respect to the total monomer containing the acrylic monomer.

The acrylic polymer may also include a polyfunctional monomer or the like as needed, for the purpose of cross-linking and the like.

Examples of the polyfunctional monomer include hexanediol di(meth)acrylate, (poly)ethyleneglycol di(meth)acrylate, (poly)propyleneglycol di(meth)acrylate, neopentylglycol di(meth)acrylate, pentaerythritol di(meth)acrylate, trimethylolpropane tri(meth)acrylate, pentaerythritol tri(meth)acrylate, dipentaerythritol hexa(meth)acrylate, epoxy(meth)acrylate, polyester (meth)acrylate and urethane (meth)acrylate.

These polyfunctional monomers can be used alone or as mixture of two or more monomers.

In terms of adhesion characteristics and the like, the amount in which the polyfunctional monomer is used is preferably about 30 mol % or less with respect to the total monomer.

A polymer having a cross-linked structure may be obtained by polymerizing a monomer mixture including monomers (for example an acrylic-based monomer) having a functional group such as a carboxyl group, hydroxyl group, epoxy group, amino group or the like in the presence of a cross-linking agent. Inclusion of this type of polymer in the adhesive layer enables improvement of self-retention properties, prevents deformation of the adhesive sheet and enables maintenance of a flat orientation of the adhesive sheet. As a result, adhesion is simply and accurately ensured onto the semiconductor wafer by using an automatic adhesive apparatus.

The acrylic polymer may be obtained by polymerizing a single monomer or a mixture of two or more monomers. The polymerization can also be any method such as solution polymerization, emulsion polymerization, mass polymerization and suspension polymerization. Thus synthesized polymer can be used directly as the base polymer of the adhesive, but it is usually suitable to add a cross-linking agent or other additives for the purpose of improving the cohesive strength of the adhesive.

It is suitable for the weight average molecular weight of the acrylic polymer to be about 300,000 or higher, and about 400,000 to 3,000,000 is preferable. The weight average molecular weight of the polymer can be found by gel permeation chromatography (GPC).

A polyfunctional (meth)acrylate and the like can be added as an internal cross-linking agent at the polymerization of the acrylic polymer, or a polyfunctional epoxy-based compound, an isocyanate-based compound, an aziridine-based compound, a melamine-based resin and the like can be added as an external cross-linking agent after the polymerization of the acrylic polymer in order to raise the weight average molecular weight of the base polymer, i.e., the acrylic polymer. A cross-linking treatment may be performed by radiation. Of these, the adhesive is preferably added an external cross-linking agent. The term “polyfunctional” here means to have two or more functional groups.

Examples of the polyfunctional epoxy-based compound include, for example, sorbitol tetraglycidyl ether, trimethylolpropane glycidyl ether, tetraglycidyl-1,3-bisaminomethylcyclohexane, tetraglycidyl-m-xylenediamine and triglycidyl-p-aminophenol.

Examples of the polyfunctional isocyanate-based compound include, for example, diphenyl methandiisosianate, tolylene diisocyanate, and hexamethylene diisocyanate.

Examples of the aziridine-based compound include, for example, 2,2-bishydroxymethylbutanol-tris[3-(1-aziridinyl)propionate] and 4,4-bis(ethyleneiminocarbonylamino)diphenylmethane.

Examples of the melamine-based compound include, for example, hexamethoxymethylmelamine.

These cross-linking agents can be used alone or as mixture of two or more compounds. The amount used can be suitably adjusted according to the composition or molecular weight of the acrylic polymer and other such factors. To promote the reaction here, dibutyltin laurate or other such cross-linking catalysts that is normally used in adhesives may be used.

In addition to the above components, the adhesive may optionally comprise any known additive in the field such as a flexibilizer, antioxidant, curative agent, filler, ultraviolet absorbing agent, light stabilizer, polymerization initiator, tackifier, pigment and the like. These additives can be used alone or as mixture of two or more additives.

As a polymerization initiator, peroxides such as hydrogen peroxide, benzoyl peroxide and t-butyl peroxide may be used. One may be preferably used by itself, or it may be combined with a reducing agent and used as a redox type of polymerization initiator. Examples of the reducing agent include ionic salts such as salts of iron, copper, cobalt, sulfite, bisulfite; amines such as triethanol amine; reducing sugar such as aldose and ketose.

Also, an azo compound such as 2,2′-azobis-2-methylpropioamidine salt, 2,2′-azobis-2,4-dimethylvaleronitrile, 2,2′-azobis-N,N′-dimethylene-isobutylamidine salt, 2,2′-azobisisobutyronitrile and 2,2′-azobis-2-methyl —N-(2-hydroxyethyl) propionamide may be used. These can be used alone or as mixture of two or more components.

In particular, it is preferable to add to the adhesive layer a photopolymerization initiator that is excited and activated by irradiation with ultraviolet rays, thereby producing radicals, so that a polyfunctional oligomer can be cured by radical polymerization.

This makes it possible to use a radiation curing type of adhesive layer, and when the adhesive sheet is affixed, plastic fluidity is imparted to the adhesive by the oligomer component, so the sheet is easier to affix, and when the adhesive sheet is peeled away, radiation can be directed at the adhesive layer to cure it and effectively lower the adhesive strength.

The phrase “radiation curing type adhesive layer” as used here means a layer whose adhesion is reduced through cross-linking/curing by radiation with an electron beam, ultraviolet rays, visible light, infrared rays or the like (of, for example about 50 mJ/m² or more).

In particular, it is suitable that the radiation curing adhesive includes a polymer, which is a photopolymerized urethane acrylate oligomer with a monomer, and a photopolymerization initiator to be the radiation curing type adhesive.

The urethane acrylate oligomer here means an oligomer having a molecular weight of about 500 to 100,000, preferably about 1,000 to 30,000, and being a bifunctional compound with ester diol as a main skeleton.

Examples of the monomer include morpholine (meth)acrylate, isobornyl (meth)acrylate, dicyclopentanyl (meth)acrylate, dicyclopentenyl (meth)acrylate and methoxylated cyclodecatriene (meth)acrylate.

The mixture ratio of the urethane (meth)acrylate oligomer and the monomer is preferably oligomer: monomer=about 95 to 5:5 to 95 (wt %), and more preferably about 50 to 70:50 to 30 (wt %).

Examples of the photopolymerization initiator include, for example,

an acetophenone photopolymerization initiator such as methoxy acetophenone, diethoxy-acetophenone (e.g., 2,2-diethoxy acetophenone), 4-phenoxydichloro acetophenone, 4-t-butyldichloro acetophenone, 2-hydroxy-2-methyl-1-phenylpropane-1-on, 1-(4-isopropylphenyl)-2-hydroxy-2-methylpropane-1-on, 1-(4-dodecylphenyl)-2-hydroxy-2-methylpropane-1-on, 4-(2-hydroxyethoxy)phenyl (2-hydroxy-2-propyl) ketone, 1-hydroxycyclohexyl phenyl ketone, 2-methyl-1-[4-(methylthio)phenyl]-2-morpholinoprophane-1 and 2,2-dimethoxy-2-phenyl acetophenone;

an •-ketol photopolymerization initiator such as 4-(2-hydroxyethoxy)phenyl(2-hydroxy-2-propyl)ketone, •-hydroxy-•, •′-dimethylacetophenone, 2-methyl-2-hydroxypropiophenon and 1-hydroxycyclohexylphenylketone;

a ketal photopolymerization initiator such as benzyldimethyl ketal;

a benzoine photopolymerization initiator such as benzoine, benzoine methyl ether, benzoine ethyl ether, benzoine isopropyl ether and benzoine isobutyl ether;

a benzophenone photopolymerization initiator such as benzophenone, benzoylbenzoate, methyl benzoylbenzoate, 4-phenyl benzophenone, hydroxy benzophenone, 4-benzoyl-4′-methyl diphenylsulfide and 3,3′-dimethyl-4-methoxybenzophenone;

a thioxanthone photopolymerization initiator such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone and 2,4-diisopropylthioxanthone;

an aromatic sulfonyl chloride photopolymerization initiator such as 2-naphthalene sulfonyl chloride;

a light-active oxime photopolymerization initiator such as 1-phenon-1,1-propanedione-2-(o-ethoxycarbonyl) oxime;

a specialized photopolymerization initiator such as •-acyloxim ester, methylphenyl glyoxylate, benzyl, camphor quinine, dibenzosuberone, 2-ethyl anthraquinone, 4′-4″-diethylisophthalophenone, ketone halide, acyl phosphinoxide and acyl phosphonate.

When reactivity is taken into account, it is suitable for the photopolymerization initiator to be added in an amount of about 0.1 parts by weight or more, and preferably about 0.5 parts by weight or more with respect to 100 parts by weight of the acrylic polymer or other such base polymer constituting the adhesive. If the amount is too large, there will be a tendency for the storage stability of the adhesive to decrease, so about 15 parts by weight or less is suitable, and about 5 parts by weight or less is preferable.

A radiation curing type oligomer other than the above oligomer may be added to the adhesive. Examples of the oligomer include polyether-based, polyester-based, polycarbonate-based, polybtadiene-based and other oligomers. These oligomers can be used alone or as mixture of two or more oligomers. The oligomer is generally added in an amount of about 30 parts by weight or less, and preferably about 10 parts by weight or less with respect to 100 parts by weight of the base polymer.

At least one layer of the adhesive layer may be adapted to contain a main component that is an acrylic-based polymer containing a carbon-carbon double bond in its molecular. The content of this type of molecule enables cross-linking in the whole layer and thereby prevents adhesive residue and the like in comparison to a formulation including an oligomer additive.

Any method known in this field can be used to introduce a carbon-carbon double bond into a side chain in the acrylic polymer molecule. For example, for ease of molecular design and so forth, examples of the method include a method in which a monomer having a functional group is copolymerized to an acrylic polymer as a comonomer component, after which this polymer and a compound which has a carbon-carbon double bond and a functional group having reactivity to the functional group are reacted (condensation, addition reaction, etc.) while radiation curing property of this carbon-carbon double bond is preserved.

Examples of the combination of the function groups include a combination of a carboxyl group and an epoxy group, a carboxyl group and an aziridine group, and a hydroxyl group and an isocyanate group. Of these, the combination of a hydroxyl group and an isocyanate group is preferable from the view point of easy reaction trace.

The functional group may be bonded in either side of the acrylic copolymer or the compound having the carbon-carbon double bond and the functional group. Of these, it is preferable that the hydroxyl group is bonded to the acrylic copolymer, and the isocyanate group is bonded to a compound having the functional group and the carbon-carbon double bond

In this case, examples of the compound having a functional group and a carbon-carbon double bond include methacryloyl isocyanate, 2-methacryloyloxyethyl isocyanate, m-isopropenyl-α,α-dimethylbenzyl isocyanate, acryloyl isocyanate, 2-acryloyloxyethyl isocyanate and 1,1-bis(acryloyloxymethyl)ethyl isocyanate.

Examples of the acrylic copolymer include a copolymer which is copolymerized with ether compounds such as the above hydroxyl-containing monomers, 2-hydroxyethylvinylether, 4-hydroxybutylvinylether and diethylene glycol monovinylether.

The acrylic copolymer having a carbon-carbon double bond can be used alone or as mixture of two or more monomers.

The thickness of the adhesive layer may be adapted to be about 1 to 60·m, preferably about 1 to 50·m, more preferably about 1 to 40·m, and still more preferably about 3 to 40·m. When the thickness of the adhesive layer is too small, the adhesive strength onto the semiconductor wafer is low, and results in a tendency for chip fly-off. When too large, there is a tendency for chip breakage to result from the deterioration in dicing accuracy and for adhesive residue to be present on the chip side face.

The adhesive sheet for dicing a semiconductor wafer according to the present invention may be provided with a plurality of layers as described above on one surface of the base film, or may be provided with a single layer, or lamination layer or the like, respectively, on both surfaces of the base film.

Further, it is preferred that a peeling film is laminated onto the adhesive layer until use in order to protect the adhesive layer.

Furthermore, there is no particular limitation on the configuration of the adhesive sheet for dicing a semiconductor wafer, and it may include any configuration of sheet shape, tape shape or the like.

In the manufacture of the adhesive sheet for dicing a semiconductor wafer of the present invention, the adhesive layer may be formed as a thin film by redissolving a collected polymer in an organic solvent as needed, and applying it directly over the base film by a known coating method such as a roll coater. Another method that can be used is to form the adhesive layer by coating a suitable removable liner (separator), and transferring this over to the base film. When the layer is formed by the transfer, any voids generated at the interface between the base film or the intermediate layer and the adhesive layer can be expanded and popped or diffused by performing a heating and pressurizing treatment such as in an autoclave after the transfer to the base film.

Also, when a polymer is manufactured by solution polymerization, emulsion polymerization or the like, the adhesive layer can be formed by coating the base film, the intermediate layer or separator or the like by a known method with the resulting polymer solution or polymer aqueous dispersion.

The adhesive layer formed in this manner may, if needed, be cross-linked in a drying step or in a subsequent light irradiation step, electron beam irradiation step, or the like.

The adhesive sheet for dicing a semiconductor wafer according to the present invention is a releasable product used in semiconductor device manufacturing. In particular, it can be used as a fixing adhesive sheet for semiconductor wafer dicing of a semiconductor wafer or the like, as or a protective/masking adhesive sheet for a semiconductor or the like, that is adhered to one surface of a semiconductor having a corrugation (for example, resulting from the disposition of a protruding electrode or the like) with a predetermined height (for example, of about 10 to 150·m).

The adhesive sheet for dicing a semiconductor wafer of the present invention can be utilized, for example, as a adhesive sheet for dicing a semiconductor wafer and for the back-grinding of a silicon semiconductor, a adhesive sheet for dicing a semiconductor wafer and for the back-grinding of a compound semiconductor, a adhesive sheet for dicing a semiconductor wafer and for the dicing of a silicon semiconductor, a adhesive sheet for dicing a semiconductor wafer and for the dicing of a compound semiconductor, a adhesive sheet for dicing a semiconductor wafer and for the dicing of a semiconductor package, a adhesive sheet for dicing a semiconductor wafer and for glass dicing, a adhesive sheet for dicing a semiconductor wafer and for ceramic dicing, for protecting a semiconductor circuit and the like. In particular, this sheet can be affixed to one side of the semiconductor wafer when a semiconductor wafer rear face is polished, for example, when the semiconductor wafer is being ground extremely thin and/or when a large-diameter wafer is being ground, etc.

The adhesive sheet of the present invention may be adapted to thermal-adhere to a semiconductor wafer. Thermal adhering is a method of adhering while applying heat at greater than or equal to the melting point of the intermediate layer. An adhering method includes use of a conventional known method, and for example, includes a method in which adhering is executed while applying pressure using a roll, a method of executing close attachment between the semiconductor wafer and the sheet under reduced pressure, a method of adhering by disposing a balloon on the sheet rear surface and inflating the balloon, or the like.

Any method of heating may be used as long as the method of heating enables application of heat to the intermediate layer until the temperature reaches the melting point of the intermediate layer. For example, such a method includes a method of heating a table on which the semiconductor is disposed, a method of heating a roller, a method of increasing the ambient temperature in the adhering region, or the like. Any heating temperature greater than or equal to the melting point of the intermediate layer may be used, and a temperature is preferred which is at least 10° C. greater than the melting point of the intermediate layer.

Dicing of the semiconductor wafer is performed after attachment of the adhesive sheet to the semiconductor wafer, dicing may be executed using a method known in this field, for example, as disclosed in JP-2006-13452-A or the like. Furthermore, peeling of the adhesive sheet after dicing is the same.

This sheet can be used in a wide range of applications such as;

removal of debris in the manufacture and machining of various products and parts that entail the peeling away of a surface protective sheet, and in various kinds of manufacturing apparatus;

surface protection against corrosion (rust), shavings and the like produced by cutting water during dicing and the like;

masking and so forth, either during the use of this adhesive sheet for dicing a semiconductor wafer or at the end of its use.

The adhesive sheet for dicing a semiconductor wafer of the present invention will now be described in detail on the basis of examples. All parts and percentages in the examples and comparative examples are by weight unless otherwise indicated.

### Example 1

As shown in Table 1, a laminate body for an intermediate layer having a thickness of 60·m and a base film having a thickness of 38·m was prepared employing a laminate method using a PET film as the base film and a resin for the intermediate layer. The resin for the intermediate layer was an ethylene-vinyl acetate copolymer resin having a melting point of 56° C.

Next, a corona process was applied to the surface of the intermediate layer provided with an adhesive layer.

The adhesive layer with a thickness of 5·m was transferred onto the face of the intermediate layer which was subjected to corona processing.

The adhesive layer was formed by an adhesive. The adhesive contain 3 parts of a photopolymerization initiator (IRAGACURE 651) (Ciba Specialty Chemicals), 3 parts of a polyisocyanate compound (CORONATE L) (Nippon Polyurethane Industry Co., Ltd.) and 100 parts of an acrylic-based polymer A. Here, the acrylic-based polymer A is formed by addition polymerization of 2-methacryloyloxyethyl isocyanate (hereafter may be referred to as “MOI”) with an acrylic-based copolymer containing a double bond introduced acrylic-base polymer (2-ethylhexyl acrylate, hereafter may be referred to as “2EHA”) and 2-hydroxyethyl acrylate (hereafter may be referred to as “HEA”). The acrylic-based polymer A has a composition of 2HEA/EHA/MOI=89 parts/11 parts/12 parts, and weight average molecular weight 850,000.

After transferring the adhesive layer, an adhesive sheet for dicing a semiconductor wafer was prepared by heating at 45° C. for 24 hours, and then by cooling to room temperature.

### Example 2

As shown in Table 1, a laminate body for an intermediate layer having a thickness of 60·m and a base film having a thickness of 38·m was prepared employing a laminate method using a PET film as the base film and a resin for the intermediate layer, the resin being a ethylene-vinyl acetate copolymer resin having a melting point of 61° C.

Next, a corona process was applied to the surface of the intermediate layer provided with an adhesive layer.

The adhesive layer of the same as in Example 1 (thickness: 5·m) was transferred onto the face of the intermediate layer which was subjected to corona processing.

After transferring the adhesive layer, an adhesive sheet for dicing a semiconductor wafer was prepared by heating at 45° C. for 24 hours, and then by cooling to room temperature.

### Example 3

As shown in Table 1, a laminate body for an intermediate layer having a thickness of 60·m and a base film having a thickness of 38·m was prepared employing a laminate method using a PET film as the base film and a resin for the intermediate layer, the resin being a ethylene-vinyl acetate copolymer resin having a melting point of 90° C.

Next, a corona process was applied to the surface of the intermediate layer provided with an adhesive layer.

The adhesive layer of the same as in Example 1 (thickness: 5·m) was transferred onto the face of the intermediate layer which was subjected to corona processing.

After transferring the adhesive layer, an adhesive sheet for dicing a semiconductor wafer was prepared by heating at 45° C. for 24 hours, and then by cooling to room temperature.

### Example 4

As shown in Table 1, a laminate body for an intermediate layer having a thickness of 60·m and a base film having a thickness of 38·m was prepared employing a laminate method using a PET film as the base film and a resin for the intermediate layer, the resin being a ethylene-vinyl acetate copolymer resin having a melting point of 61° C.

Next, a corona process was applied to the surface of the intermediate layer provided with an adhesive layer.

The adhesive layer of the same as in Example 1 (thickness: 20·m) was transferred onto the face of the intermediate layer which was subjected to corona processing.

After transferring the adhesive layer, an adhesive sheet for dicing a semiconductor wafer was prepared by heating at 45° C. for 24 hours, and then by cooling to room temperature.

### Example 5

As shown in Table 1, a laminate body for an intermediate layer having a thickness of 40·m and a base film having a thickness of 38·m were prepared employing a laminate method using a PET film as the base film and a resin for the intermediate layer, the resin being a ethylene-vinyl acetate copolymer resin having a melting point of 61° C.

Next, a corona process was applied to the surface of the intermediate layer provided with an adhesive layer.

The adhesive layer of the same as in Example 1 (thickness: 20·m) was transferred onto the face of the intermediate layer which was subjected to corona processing.

After transferring the adhesive layer, an adhesive sheet for dicing a semiconductor wafer was prepared by heating at 45° C. for 24 hours, and then by cooling to room temperature.

### Comparative Example 1

As shown in Table 1, a LDPE film was used as a base film. Next, a corona process was applied to the surface of the base film provided with an adhesive layer.

The adhesive layer of the same as in Example 1 (thickness: 5·m) was transferred onto the face of the intermediate layer which was subjected to corona processing.

After transferring the adhesive layer, an adhesive sheet for dicing a semiconductor wafer was prepared by heating at 45° C. for 24 hours, and then by cooling to room temperature.

### Comparative Example 2

As shown in Table 1, a LDPE film was used as a base film.

Next, a corona process was applied to the surface of the base film provided with an adhesive layer.

The adhesive layer of the same as in Example 1 (thickness: 50 μm) was transferred onto the face of the intermediate layer which was subjected to corona processing.

After transferring the adhesive layer, an adhesive sheet for dicing a semiconductor wafer was prepared by heating at 45° C. for 24 hours, and then by cooling to room temperature.

### Comparative Example 3

As shown in Table 1, a LDPE film was used as a base film.

Next, a corona process was applied to the surface of the base film provided with an adhesive layer.

The adhesive layer of the same as in Example 1 (thickness: 50 μm) was transferred onto the face of the intermediate layer which was subjected to corona processing.

After transferring the adhesive layer, an adhesive sheet for dicing a semiconductor wafer was prepared by heating at 45° C. for 24 hours, and then by cooling to room temperature.

### Comparative Example 4

As shown in Table 1, a PET film was used as a base film.

Next, a corona process was applied to the surface of the base film provided with an adhesive layer.

The adhesive layer of the same as in Example 1 (thickness: 50 μm) was transferred onto the face of the intermediate layer which was subjected to corona processing.

After transferring the adhesive layer, an adhesive sheet for dicing a semiconductor wafer was prepared by heating at 45° C. for 24 hours, and then by cooling to room temperature.

TABLE 1

| | | | Thickness |
|---|---|---|---|
| | Base film | Intermediate layer | of adhesive |
| | material/thickness | material/thickness (m.p.) | layer |
| Ex. 1 | PET/38•m | EVA/60•m (56° C.) | 5 μm |
| Ex. 2 | PET/38 μm | EVA/60 μm (61° C.) | 5 μm |
| Ex. 3 | PET/38 μm | EVA/60 μm (90° C.) | 5 μm |
| Ex. 4 | PET/38 μm | EVA/60 μm (61° C.) | 20 μm |
| Ex. 5 | PET/38 μm | EVA/40 μm (61° C.) | 20 μm |
| Comp. Ex. 1 | LDPE/100 μm | — | 5 μm |
| Comp. Ex. 2 | LDPE/100 μm | — | 50 μm |
| Comp. Ex. 3 | LDPE/100 μm | — | 50 μm |
| Comp. Ex. 4 | PET/100 μm | — | 50 fin |

In Table 1, EVA in the intermediate layer is

EVA (56° C.): ethylene-vinyl acetate copolymer resin having a melting point of 56° C. (Mitsui Du Pont Polychemicals Co. Ltd.; trade name “(registered trademark) EVAFLEX”, product number:EV5773W),

EVA (61° C.): ethylene-vinyl acetate copolymer resin having a melting point of 61° C. (Mitsui Du Pont Polychemicals Co. Ltd.; trade name “(registered trademark) EVAFLEX”, product number:EV5773ET), and

EVA (90° C.): ethylene-vinyl acetate copolymer resin having a melting point of 90° C. (Mitsui Du Pont Polychemicals Co. Ltd.; trade name “(registered trademark) EVAFLEX”, product number:EV560).

The melting point of PET used as the base film was 250° C. A melting point in this case was measured as a temperature at which elution commenced under a weight of 5.0 kg using an extrusion blastometer.

The following evaluation was performed with respect to the adhesive sheet manufactured in Examples 1 to 5 and Comparative Examples 1 to 4. The results thereof are shown in Table 2.

### Chipping Evaluation

50 diced chips were collected, and the ultimately cut face of the side faces of each chip was observed. The depth of chip breakage (chipping) was measured, and the maximum depth in one chip was taken to be the dimension of the chipping in that chip. Each of the 50 chips was respectively measured, and the maximum values and average values are shown in Table 2. Herein, chipping having a dimension which is at least half of the chip thickness (a maximum value of at least 100·m) is taken to be impermissible.

### Water Penetration and Chip Fly-Off

The adhesive sheets of the Examples and the Comparative Examples were attached at 5 mm/sec at the temperature shown in Table 2 (for example, 60° C.) to a silicon wafer having a bump electrode with a height of 30·m, and fixed to a ring frame (Disco Corporation).

A dicing apparatus (Disco Corporation DFD-651) was used to execute full-cut dicing under the conditions of blade: NBC-ZH2050-27HECC, rotation speed 40000 rpm, blade penetration: 80 mm/sec, and cutting depth: 30·m in order to dice a silicon wafer with a thickness of 200·m to a 10 mm×10 mm size.

Observation was made of the state of chip fly-off and water penetration onto the dicing tape adhesive surface during dicing.

TABLE 2

| | | Chipping | | |
|---|---|---|---|---|
| | Attaching | (max./average) : | Water | Chip |
| | Temp. | Evaluation | Penetration | Fly-Off |
| Ex. 1 | 60° C. | 50/34: permissible | no | 0 |
| Ex. 2 | 65° C. | 55/37: permissible | no | 0 |
| Ex. 3 | 98° C. | 48/32: permissible | no | 0 |
| Ex. 4 | 65° C. | 60/42: permissible | no | 0 |
| Ex. 5 | 65° C. | 52/35: permissible | no | 0 |
| Comp. Ex. 1 | 65° C. | no chips | | 100 |
| Comp. Ex. 2 | 65° C. | 162/87: impermissible | no | 0 |
| Comp. Ex. 3 | 65° C. | 105/61: impermissible | occurred | 30 |
| Comp. Ex. 4 | 65° C. | 140/84: impermissible | no | 0 |

The adhesive sheet for dicing a semiconductor wafer according to the present invention is not only used for temporary fixing or fixing during dicing or polishing of a semiconductor wafer or the like, but may be used for protective or masking applications for wafers or the like during various wafer processing steps, and is also useful as an adhesive sheet for dicing a semiconductor wafer which requires releasability.

It is to be understood that although the present invention has been described in relation to preferred embodiments thereof, various other embodiments and variants may occur to those skilled in the art as within the scope and spirit of the invention, and such other embodiments and variants are intended to be covered by the following claims.

What is claimed is:

1. An adhesive sheet for dicing a semiconductor wafer having a laminate comprising;
a base film,
an intermediate layer and
an adhesive layer,
the intermediate layer is formed by a thermoplastic resin having a melting point of 50 to 100° C.; and
the base film has a higher melting point than the intermediate layer.

2. The adhesive sheet according to claim 1, wherein the base film, the intermediate layer and the adhesive layer are laminated in that order.

3. The adhesive sheet according to claim 1, wherein the melting point of the base film is at least 20° C. higher than the melting point of the intermediate layer.

4. The adhesive sheet according to claim 1, wherein the main component of the adhesive layer is an acrylic-based polymer.

5. The adhesive sheet according to claim 1, wherein the intermediate layer has a thickness of 3 to 200·m.

6. The adhesive sheet according to claim 1, wherein the adhesive layer has a thickness of 1 to 60·m.

7. A method for dicing a semiconductor wafer comprising the steps of:
adhering the adhesive sheet according to claim 1 to a corrugated surface of a semiconductor wafer, and
dicing the semiconductor wafer.
